(19) United States
(12) Patent Application Publication
(10) Pub. No.: US 2024/0038507 A1
(43) Pub. Date: Feb. 1, 2024

(54) SUBSTRATE SUPPORT AND PLASMA PROCESSING APPARATUS

(71) Applicant: Tokyo Electron Limited, Tokyo (JP)

(72) Inventor: Satoshi TAGA, Kurokawa-gun (JP)

(73) Assignee: Tokyo Electron Limited, Tokyo (JP)

(21) Appl. No.: 18/360,384

(22) Filed: Jul. 27, 2023

(30) Foreign Application Priority Data
Jul. 28, 2022 (JP) 2022-120333
Jun. 26, 2023 (JP) 2023-104051

(51) Int. Cl. H01J 37/32

(52) U.S. Cl. CPC H01J 37/32715; H01J 2237/2007

(57) ABSTRACT

A disclosed substrate support is used in a plasma processing apparatus. The substrate support includes a base, an electrostatic chuck, and a plurality of electrodes. The base is formed of ceramic. The electrostatic chuck is disposed on the base. The electrostatic chuck includes a central region, an annular region, and a coating layer. The central region is configured to support a substrate placed thereon. The annular region extends to surround the central region and is configured to support an edge ring placed thereon. The coating layer is formed of ceramic. The coating layer is configuring a surface of the electrostatic chuck. The plurality of electrodes include a first metal layer and a second metal layer. The first metal layer is disposed between the central region and the base. The second metal layer is disposed between the annular region and the base.

### CROSS-REFERENCE TO RELATED APPLICATIONS

This application is based on and claims the benefit of priority from Japanese Patent Application No. 2023-104051 filed on Jun. 26, 2023 and Japanese Patent Application No. 2022-120333 filed on Jul. 28, 2022, the entire contents of which are incorporated herein by reference.

### FIELD

The present disclosure relates to a substrate support and a plasma processing apparatus.

### BACKGROUND

A plasma processing apparatus is used for plasma processing on a substrate. Japanese Unexamined Patent Publication No. 2020-107881 discloses a capacitively coupled plasma processing apparatus that is a type of plasma processing apparatus. The plasma processing apparatus disclosed in Japanese Unexamined Patent Publication No. 2020-107881 includes a chamber and a substrate support. The substrate support includes abase and an electrostatic chuck. The base is formed of metal. The electrostatic chuck includes a coating layer formed of ceramic. The temperature of the substrate support is controlled by a refrigerant and a heat transfer gas.

### SUMMARY

In an exemplary embodiment, a substrate support used in a plasma processing apparatus is provided. The substrate support includes a base, an electrostatic chuck, and a plurality of electrodes. The base is formed of ceramic. The electrostatic chuck is disposed on the base. The electrostatic chuck includes a central region, an annular region, and a coating layer. The central region is configured to support a substrate placed thereon. The annular region extends to surround the central region and is configured to support an edge ring placed thereon. The coating layer is formed of ceramic. The coating layer is configuring a surface of the electrostatic chuck. The plurality of electrodes include a first metal layer and a second metal layer. The first metal layer is disposed between the central region and the base. The second metal layer is disposed between the annular region and the base.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a diagram for describing a configuration example of a capacitively coupled plasma processing apparatus.

FIG. 2 is a partially enlarged sectional view of a substrate support according to one exemplary embodiment.

FIG. 3 is a partially enlarged sectional view of a substrate support according to another exemplary embodiment.

FIG. 4 is a partially enlarged sectional view of a substrate support according to still another exemplary embodiment.

FIG. 5 is an enlarged sectional view of a power feed line according to one exemplary embodiment.

FIG. 6 is an enlarged sectional view of a power feed line according to another exemplary embodiment.

FIG. 7 is an enlarged sectional view of a power feed line according to still another exemplary embodiment.

FIG. 8 is an enlarged sectional view of a power feed line according to still another exemplary embodiment.

FIG. 9 is an enlarged sectional view of a power feed line according to still another exemplary embodiment.

FIG. 10 is a partially enlarged sectional view of a substrate support according to still another exemplary embodiment.

FIG. 11 is a partially enlarged sectional view of a substrate support according to still another exemplary embodiment.

FIG. 12 is a partially enlarged sectional view of a substrate support according to still another exemplary embodiment.

### DETAILED DESCRIPTION

Hereinafter, various exemplary embodiments will be described.

In an embodiment, A substrate support used in a plasma processing apparatus is provided. The substrate support includes a base, an electrostatic chuck, and a plurality of electrodes. The base is formed of ceramic. The electrostatic chuck is disposed on the base. The electrostatic chuck includes a central region, an annular region, and a coating layer. The central region is configured to support a substrate placed thereon. The annular region extends to surround the central region and is configured to support an edge ring placed thereon. The coating layer is formed of ceramic. The coating layer is configuring a surface of the electrostatic chuck. The plurality of electrodes include a first metal layer and a second metal layer. The first metal layer is disposed between the central region and the base. The second metal layer is provided between the annular region and the base.

In the above embodiment, the coating layer of the electrostatic chuck and the base are formed of ceramic. Therefore, the difference in thermal expansion coefficient between the electrostatic chuck and the base is relatively small. Therefore, according to the above embodiment, it is possible to suppress damage to the substrate support due to the difference in the thermal expansion coefficient between the base and the electrostatic chuck.

In one exemplary embodiment, the electrostatic chuck may include a first resin layer, an electrode layer, and a second resin layer. The first resin layer may be disposed on the base. The electrode layer may be disposed on the first resin layer. The second resin layer may be disposed between the electrode layer and the coating layer.

In an exemplary embodiment, the base may include a first base and a second base. The second base may be disposed on the first base. The first metal layer may be disposed on the second base. A plurality of electrodes may include a third metal layer. The third metal layer may be disposed between the first base and the second base. The third metal layer may bond the first base and the second base to each other. In this embodiment, the first base and the second base are bonded to each other by the third metal layer having a relatively high thermal conductivity. Therefore, according to this embodiment, the heat transfer efficiency from the second base to the first base is improved.

In one exemplary embodiment, the second metal layer may be disposed on the second base.

In one exemplary embodiment, the first base may include a peripheral edge portion. The peripheral edge portion may protrude outward with respect to the outer edge of the second base. The plurality of electrodes may include a fourth metal layer. The fourth metal layer may be disposed on the peripheral edge portion. The third metal layer and the fourth metal layer may be electrically connected to each other. In this embodiment, the fourth metal layer electrically connected to the third metal layer is provided on the peripheral edge portion. Therefore, by connecting a power feed line to the fourth metal layer at the outer side of the base, it is possible to establish an electrical path to the third metal layer without going through the interior of the base.

In one exemplary embodiment, the first metal layer may be disposed on the second base. The second metal layer may be disposed on the first base.

In one exemplary embodiment, the substrate support may provide at least one hole. The at least one hole may extend from a lower surface of the base. The substrate support may include at least one power feed line. The at least one power feed line may be connected to at least one of the plurality of electrodes. The at least one power feed line may extend through the at least one hole.

In one exemplary embodiment, the at least one power feed line may include a power feed conductor. The power feed conductor may extend in the at least one hole.

In one exemplary embodiment, the power feed conductor may be formed of metal.

In one exemplary embodiment, the metal may be titanium, molybdenum, or tungsten.

In one exemplary embodiment, the power feed conductor may be formed of silicon carbide.

In one exemplary embodiment, the power feed conductor may be formed of silicon.

In one exemplary embodiment, the at least one power feed line may include a main body and at least one metal film. The at least one metal film may cover a surface of the main body.

In one exemplary embodiment, the at least one metal film may include a first metal film and a second metal film. The second metal film may be formed of metal different from metal forming the first metal film. The second metal film may be disposed between the first metal film and the main body.

In one exemplary embodiment, the at least one metal film may include palladium, nickel, or gold.

In one exemplary embodiment, the power feed line may include an inner wall. The inner wall may define the at least one hole.

In one exemplary embodiment, the inner wall may be formed of a conductor film.

In another exemplary embodiment, a plasma processing apparatus is provided. The plasma processing apparatus includes a plasma processing chamber and a substrate support. The substrate support is the substrate support according to any one of exemplary embodiments described above. The substrate support is disposed in the plasma processing chamber.

Hereinafter, various exemplary embodiments will be described. In the drawings, the same or corresponding parts are denoted by the same reference numerals.

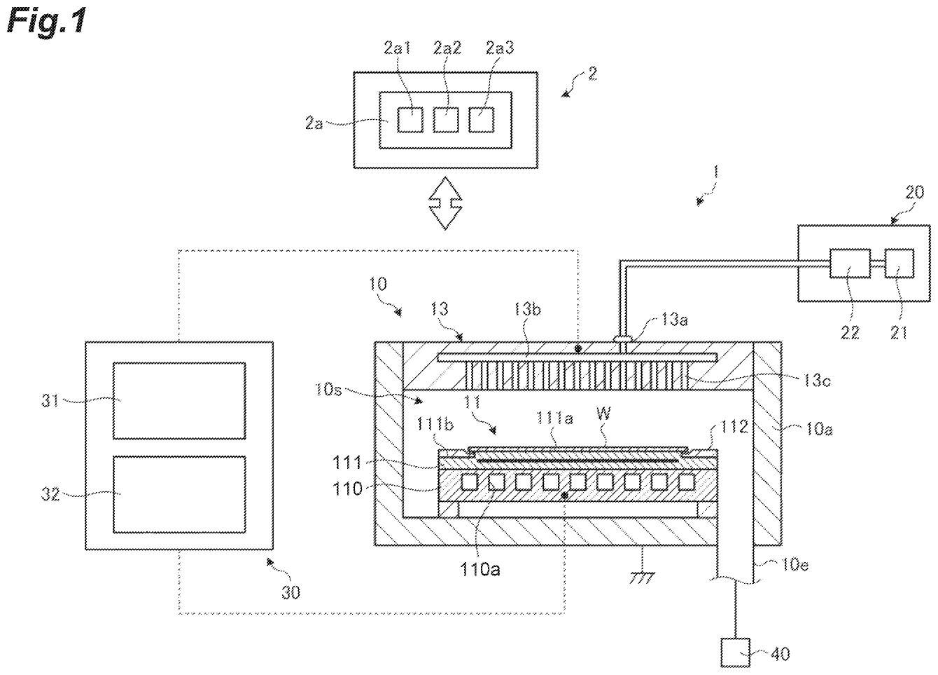

An example configuration of a plasma processing system will now be described. FIG. 1 illustrates an example configuration of a capacitively coupled plasma processing system.

The plasma processing system includes a capacitively coupled plasma processing apparatus 1 and a controller 2. The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 has at least one gas inlet for supplying at least one process gas to the plasma processing space 10s and at least one gas outlet for exhausting gases from the plasma processing space 10s. The plasma processing chamber 10 is grounded. The showerhead 13 and the substrate support 11 are electrically insulated from the housing of the plasma processing chamber 10.

The substrate support 11 includes abase 110 and an electrostatic chuck 111. The electrostatic chuck 111 is provided on the base 110. The electrostatic chuck 111 includes a central region 111a for supporting a substrate W and an annular region 111b for supporting an edge ring 112. A wafer is an example of the substrate W. The annular region 111b surrounds the central region 111a of the electrostatic chuck 111 in a plan view. The substrate W is disposed on the central region 111a, and the edge ring 112 is disposed on the annular region 111b to surround the substrate W on the central region 111a.

The substrate support 11 may also include a temperature adjusting module that is configured to adjust at least one of the electrostatic chuck 111, the edge ring 112, and the substrate to a target temperature. The temperature adjusting module may be one or more beaters, a heat transfer medium, a flow passage 110a, or any combination thereof. A heat transfer fluid, such as brine or gas, flows through the flow passage 110a. In an embodiment, the flow passage 110a is formed in the base 110, and the one or more heaters are disposed in the ceramic member 1111a of the electrostatic chuck 11. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 includes at least one radio frequency power source 31 and at least one bias power source 32. The at least one radio frequency power source 31 is electrically connected to at least one radio frequency electrode through an impedance matching circuit. The at least one radio frequency electrode may be one or more electrodes in the substrate support 11. Alternatively, the at least one radio frequency electrode may be an upper electrode. The at least one radio frequency power source 31 is configured to supply a source radio frequency power to the at least one radio frequency electrode to generate plasma from a gas in the plasma processing chamber 10. The source radio frequency power has a frequency in a range of 10 MHz to 150 MHz.

The at least one bias power source 32 is configured to supply an electric bias to at least one bias electrode in the substrate support 11. The at least one bias electrode may be one or more electrodes in the substrate support 11. The electric bias has a bias frequency suitable for drawing ions from the plasma. The bias frequency is a frequency in a range of 100 kHz to 60 MHz.

The electric bias may be a bias radio frequency power having the bias frequency. In this case, the at least one bias power source 32 is electrically connected to the at least one bias electrode through an impedance matching circuit. Alternatively, the electric bias may be a voltage pulse periodically applied to the at least one bias electrode at a time interval that is the reciprocal of the bias frequency. The voltage pulse may be a pulse of a negative voltage or a negative DC voltage.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line such as a local area network (LAN).

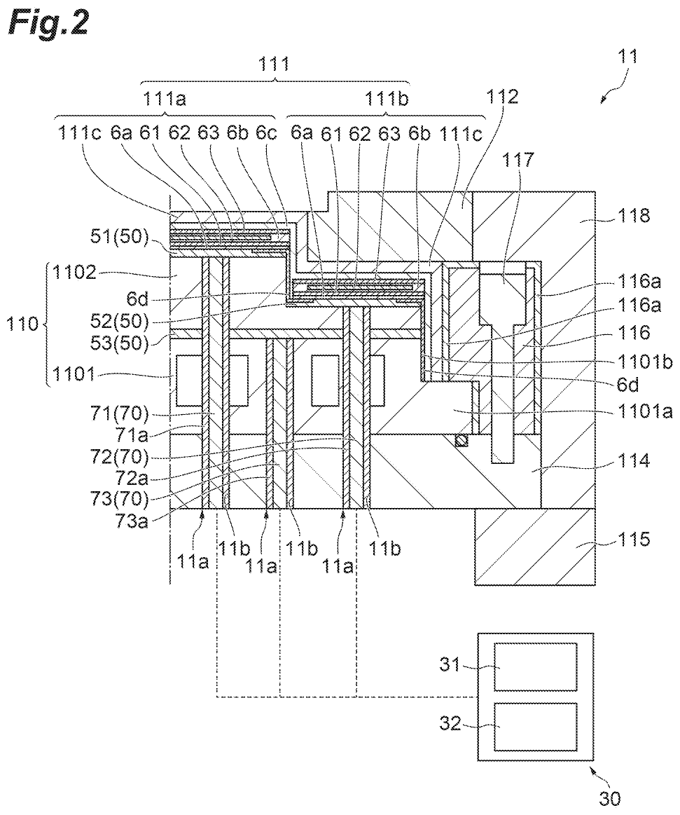

Hereinafter, a substrate support according to one exemplary embodiment will be described with reference to FIG. 2. FIG. 2 is a partially enlarged sectional view of the substrate support according to one exemplary embodiment. The substrate support 11 illustrated in FIG. 2 includes the base 110 and the electrostatic chuck 111 described above. The base 110 is formed of ceramic such as silicon carbide or aluminum nitride.

The substrate support 11 further includes a plurality of electrodes 50. The plurality of electrodes 50 include a first metal layer 51 and a second metal layer 52. The first metal layer 51 is disposed between the central region 111a of the electrostatic chuck 111 and the base 110. The second metal layer 52 is disposed between the annular region 111b of the electrostatic chuck 111 and the base 110. The first metal layer 51 may be positioned above the second metal layer 52.

As described above, the electrostatic chuck 111 is provided on the base 110. The electrostatic chuck 111 includes a central region 111a, an annular region 111b, and a coating layer 111c. The central region 111a is configured to support the substrate W placed thereon. The annular region 111b extends to surround the central region 111a and is configured to support the edge ring 112 placed thereon. The coating layer 111c configures the surface of the electrostatic chuck 111. The coating layer 111c is formed of ceramic such as aluminum nitride, aluminum oxide, or yttrium oxide.

In the substrate support 11, the coating layer 111c of the electrostatic chuck 111 and the base 110 are formed of ceramic. Therefore, the difference in thermal expansion coefficient between the electrostatic chuck 111 and the base 110 is relatively small. Therefore, it is possible to suppress damage to the substrate support 11 due to the difference in the thermal expansion coefficient between the base 110 and the electrostatic chuck 111.

In one embodiment, each of the central region 111a and the annular region 111b of the electrostatic chuck 111 may further include a first resin layer 61, an electrode layer 62, and a second resin layer 63. The first resin layer 61 is disposed on the base 110. The first resin layer 61 is fixed to the base 110 through, for example, an adhesion layer 6a. The electrode layer 62 is disposed on the first resin layer 61. The electrode layer 62 is disposed between the first resin layer 61 and the second resin layer 63. The second resin layer 63 is disposed between the electrode layer 62 and the coating layer 111c. The first resin layer 61 and the second resin layer 63 are adhered to the electrode layer 62 by, for example, an adhesion layer 6b. The coating layer 111c is fixed to the adhesion layer 6b through a bonding layer 6c. The adhesion layers 6a and 6b may be formed of an adhesive. The bonding layer 6c may be composed of ceramic particles, resins, or silane-based agents.

A DC power source is electrically connected to the electrode layer 62. When a voltage from the DC power source is applied to the electrode layer 62, electrostatic attraction force is generated between the substrate W and the central region 111a and between the edge ring 112 and the annular region 111b. As a result, the substrate W is held by the central region 111a and the edge ring 112 is held by the annular region 11b.

In one embodiment, the base 110 may include a first base 1101 and a second base 1102. The second base 1102 is disposed on the first base 1101. The first base 1101 and the second base 1102 may be formed of the same type of ceramic. Alternatively, the first base 1101 and the second base 1102 may be formed of different types of ceramics. For example, the first base 1101 may be formed of silicon carbide, and the second base 1102 may be formed of aluminum nitride.

A third metal layer 53 may be disposed between the first base 1101 and the second base 1102. The third metal layer 53 is included in the plurality of electrodes 50. The third metal layer 53 bonds the first base 1101 and the second base 1102 to each other. In this way, the first base 1101 and the second base 1102 are bonded to each other by the third metal layer 53 having a relatively high thermal conductivity. Therefore, heat transfer efficiency from the second base 1102 to the first base 1101 is improved.

The first metal layer 51 is provided on the second base 1102. Specifically, the first metal layer 51 is provided on the upper surface of a central portion of the second base 1102. The second metal layer 52 may be provided on the second base 1102, as illustrated in FIG. 2. Specifically, the second metal layer 52 may be provided on the upper surface of a peripheral edge portion of the second base 1102. In the second base 1102, the peripheral edge portion extends in the circumferential direction to surround the central portion. In the second base 1102, the thickness of the peripheral edge portion is smaller than the thickness of the central portion. In the second base 1102, the position of the upper surface of the peripheral edge portion may be lower than the position of the upper surface of the central portion.

In one embodiment, the substrate support 11 may further include an insulating film 6d. The insulating film 6d may cover an outer edge portion of the first metal layer 51, an inner edge portion and an outer edge portion of the second metal layer 52, a side surface of a central portion of the first base 1101 which will be described later, and a side surface of a central portion and a side surface of the peripheral edge portion of the second base 1102.

In one embodiment, the first base 1101 may include the central portion and a peripheral edge portion 1101a. The second base 1102 is provided on the central portion of the first base 1101. The peripheral edge portion 1101a protrudes outward with respect to the outer edge of the second base 1102. In addition, the peripheral edge portion 1101a extends along the circumferential direction to surround the central portion of the first base 1101. In the first base 1101, the thickness of the peripheral edge portion 1101a may be smaller than the thickness of the central portion. In the first base 1101, the position of an upper surface of the peripheral edge portion 1101a may be lower than the position of an upper surface of the central portion.

In one embodiment, the substrate support 11 may further include a base plate 114 and an insulating support ring 115. The base plate 114 is provided under the first base 1101. The base plate 114 supports the first base 1101 mounted thereon. The base plate 114 is formed of metal.

The insulating support ring 115 is provided under the base plate 114. The insulating support ring 115 supports the base plate 114 mounted thereon. The insulating support ring 115 is formed of an insulating material. The insulating support ring 115 electrically insulates the substrate support 11 from the plasma processing chamber 10.

The first base 1101 may be fixed to the base plate 114. For example, the first base 1101 may be fixed to the base plate 114 by holding the peripheral edge portion 1101a between the clamp ring 116 and the base plate 114. The clamp ring 116 may be formed of metal, and the surface thereof may be covered with an insulating film 116a. The clamp ring 116 is fixed to the base plate 114 by a fixing screw 117. The clamp ring 116 and the fixing screw 117 may be covered with an insulating cover 118.

In one embodiment, the substrate support 11 provides at least one hole 11a. In the example illustrated in FIG. 2, the substrate support 11 provides a plurality of holes 11a. Each of the plurality of holes 11a extends from a lower surface of the base 110. For example, each of the plurality of holes 11a extends toward each of the plurality of electrodes 50.

The substrate support 11 includes at least one power feed line 70. In one embodiment, the substrate support 11 includes a plurality of power feed lines 70. Each of the plurality of power feed lines 70 is connected to the corresponding electrode among the plurality of electrodes 50. Each of the plurality of power feed lines 70 extends through the corresponding hole among the plurality of holes 11a and is connected to the corresponding electrode among the plurality of electrodes 50.

As illustrated in FIG. 2, the plurality of power feed lines 70 may include power feed lines 71, 72, and 73. The power feed line 71 is connected to the first metal layer 51. The power feed line 72 is connected to the second metal layer 52. The power feed line 73 is connected to the third metal layer 53. Each of the power feed lines 71, 72, and 73 may be formed of metal. In this case, the power feed lines 71, 72, and 73 are respectively disposed in the sleeves 71a, 72a, and 73a. Each of the sleeves 71a, 72a, and 73a is formed of an insulating material. The insulating material that forms each of the sleeves 71a, 72a, and 73a is, for example, ceramic.

The plurality of electrodes 50 are electrically connected to the electric power source 30 through the plurality of power feed lines 70. Either one or both of the source radio frequency power and the electric bias are supplied from the electric power source 30 to each of the plurality of electrodes 50. For example, the electric bias described above is supplied to the first metal layer 51 and the second metal layer 52, and the source radio frequency power is supplied to the third metal layer 53.

The DC power source that applies a voltage to the electrode layer 62 may be electrically connected to the electrode layer 62 through power feed lines provided in the substrate support 11 similar to the plurality of power feed lines 70.

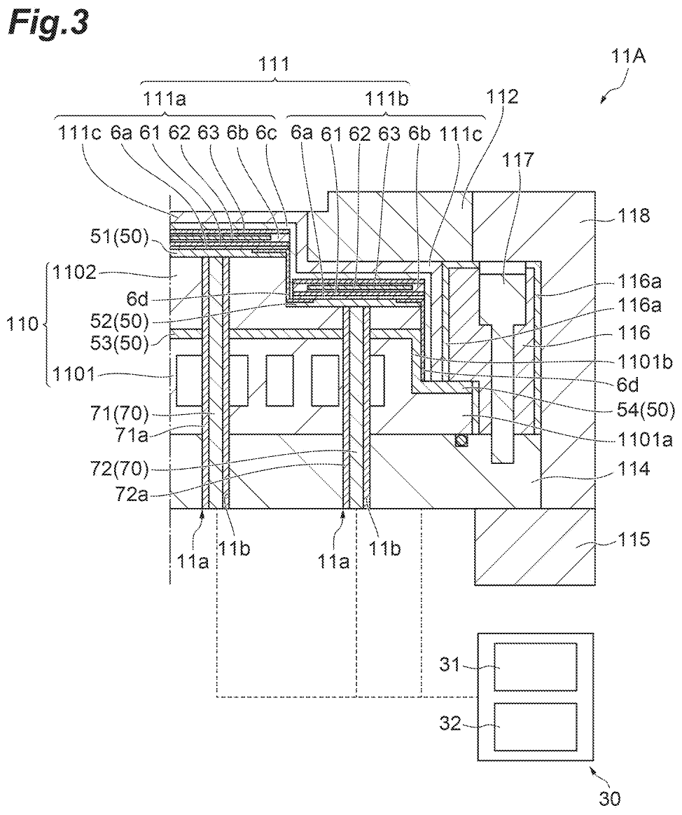

Hereinafter, reference is made to FIG. 3. FIG. 3 is a partially enlarged sectional view of a substrate support according to another exemplary embodiment. The substrate support 11A illustrated in FIG. 3 can be adopted as a substrate support 11 of the plasma processing apparatus 1. Hereinafter, the substrate support 11A will be described from the viewpoint of the differences between the substrate support 11A and the substrate support 11 illustrated in FIG. 2.

In the substrate support 11A, the plurality of electrodes 50 further include a fourth metal layer 54. The fourth metal layer 54 is provided on the peripheral edge portion 1101a. The third metal layer 53 and the fourth metal layer 54 are electrically connected to each other. In one embodiment, the third metal layer 53 and the fourth metal layer 54 are connected to each other by a metal layer formed on the surface of the side surface 1101b. The third metal layer 53, the fourth metal layer 54, and the metal layer formed on the surface of the side surface 1101b may be formed as an integrated metal layer.

In the substrate support 11A, the insulating film 116a is provided to expose the metallic lower surface of the clamp ring 116. The lower surface of the clamp ring 116 is in close contact with the base plate 114 and the fourth metal layer 54. Therefore, the fourth metal layer 54 and the base plate 114 are electrically connected to each other by the clamp ring 116. Therefore, the third metal layer 53 is connected to a power feed line that includes the fourth metal layer 54, the clamp ring 116, and the base plate 114.

In the substrate support 11A, a part of the electric power source 30 may be electrically connected to the base plate 114. For example, the radio frequency power source 31 may be electrically connected to the base plate 114.

In the substrate support 11A, the fourth metal layer 54 electrically connected to the third metal layer 53 is disposed on the peripheral edge portion 1101a. Therefore, by connecting a power feed line to the fourth metal layer 54 at the outer side of the base 110, it is possible to establish an electrical path to the third metal layer 53 without going through the interior of the base 110.

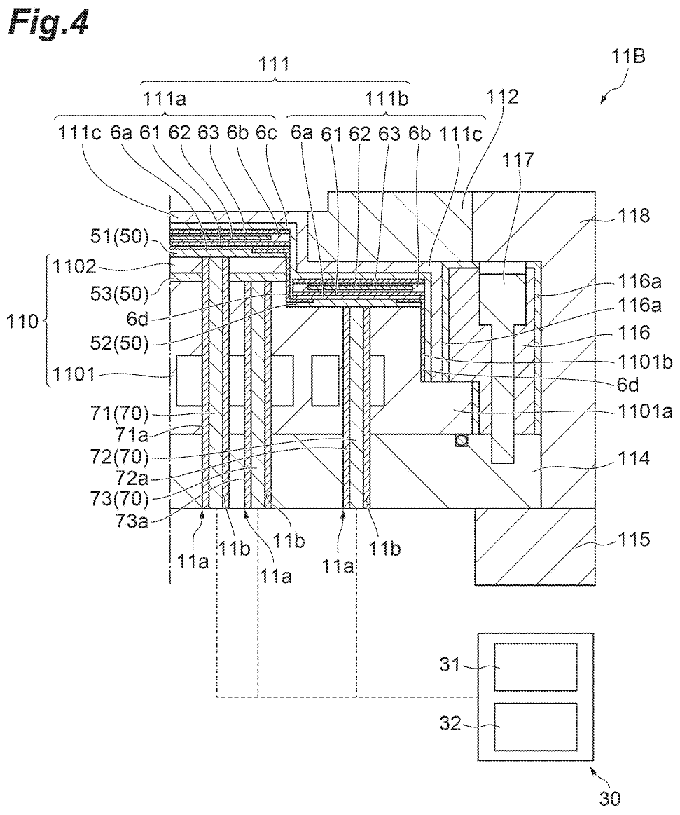

Hereinafter, reference is made to FIG. 4. FIG. 4 is a partially enlarged sectional view of a substrate support according to still another exemplary embodiment. The substrate support 11B illustrated in FIG. 4 can be adopted as a substrate support 11 in the plasma processing apparatus 1. Hereinafter, the substrate support 11B will be described from the viewpoint of the differences between the substrate support 11B and the substrate support 11 illustrated in FIG. 2.

In the substrate support 11B, the second metal layer 52 is disposed on the first base 1101. Specifically, in the substrate support 11B, the first base 1101 includes an intermediate portion in addition to the central portion and the peripheral edge portion 1101a described above. In the first base 1101, the intermediate portion extends in the circumferential direction between the central portion and the peripheral edge portion 1101a. The second base 1102 is disposed on the central portion of the first base 1101 and is bonded to the central portion of the first base 1101 through the third metal layer 53.

In the substrate support 11B, the second metal layer 52 is disposed on the intermediate portion of the first base 1101. In the first base 1101, the thickness of the intermediate portion may be smaller than the thickness of the central portion and larger than the thickness of the peripheral edge portion 1101a. In the first base 1101, the position of an upper surface of the intermediate portion may be lower than the position of the upper surface of the central portion and higher than the position of the upper surface of the peripheral edge portion 1101a.

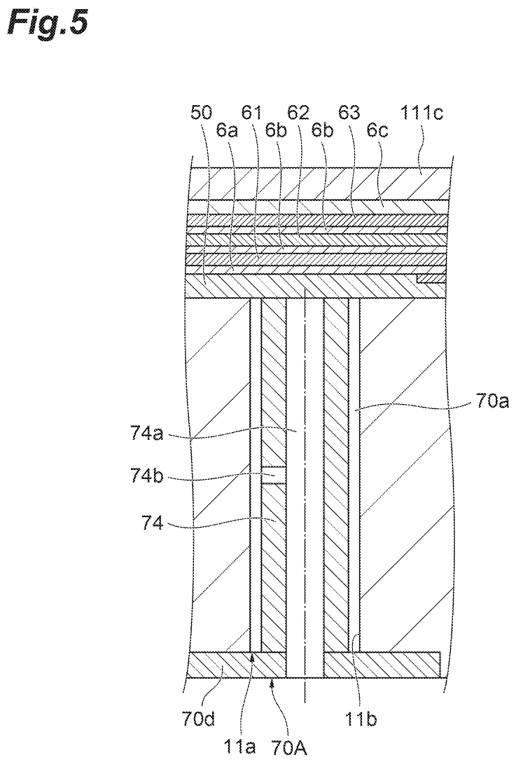

Hereinafter, reference is made to FIG. 5. FIG. 5 is an enlarged sectional view of a power feed line according to one exemplary embodiment. The power feed line 70A illustrated in FIG. 5 can be adopted as each of the one or the plurality of power feed lines 70 described above. The power feed line 70A includes a power feed conductor 74 and an electrode 70d. The electrode 70d is a metal layer provided on the lower surface of the base 110. The power feed conductor 74 extends in the hole 11a. The power feed conductor 74 is provided to provide a gap 70a between the power feed conductor 74 and the inner wall 11b of the hole 11a. The power feed conductor 74 may have a cylindrical shape. In this case, the power feed conductor 74 provides a gap 74a at the center thereof. The power feed conductor 74 may further provide a through-hole 74b that communicates the gap 74a and the gap 70a with each other. The power feed conductor 74 electrically connects the electrode 70d and the corresponding electrode among the plurality of electrodes 50 to each other.

In one embodiment, the power feed conductor 74 may be formed of metal. The metal that forms the power feed conductor 74 may be titanium, molybdenum, or tungsten. Alternatively, the power feed conductor 74 may be formed of silicon carbide. Alternatively, the power feed conductor 74 may be formed of silicon.

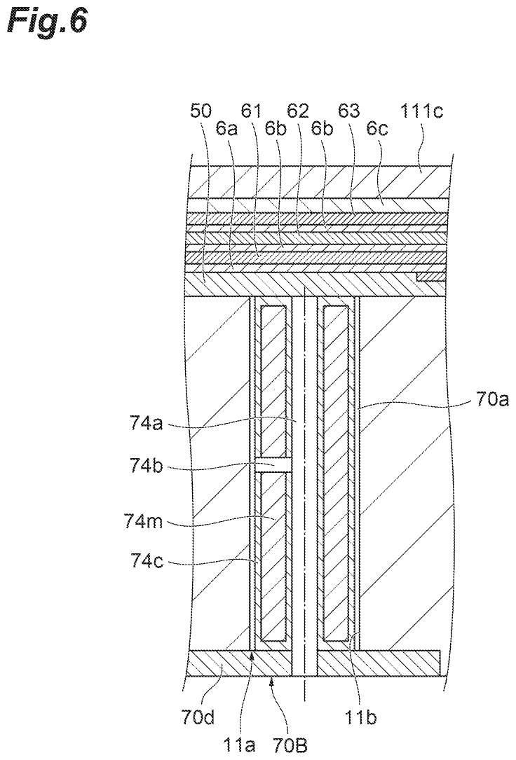

Hereinafter, reference is made to FIG. 6. FIG. 6 illustrates an enlarged sectional view of a power feed line according to another exemplary embodiment. The power feed line 70B illustrated in FIG. 6 can be adopted as each of the one or the plurality of power feed lines 70 described above. The power feed line 70B includes a main body 74m and at least one metal film 74c. The main body 74m, as with the power feed conductor 74, may have the cylindrical shape and provide the gap 74a and the through-hole 74b. The main body 74m may be formed of silicon carbide. Alternatively, the main body 74m may be formed of metal such as titanium, molybdenum, or tungsten, or silicon. At least one metal film 74c covers the surface of the main body 74m. The metal film 74c may contain palladium, nickel, or gold.

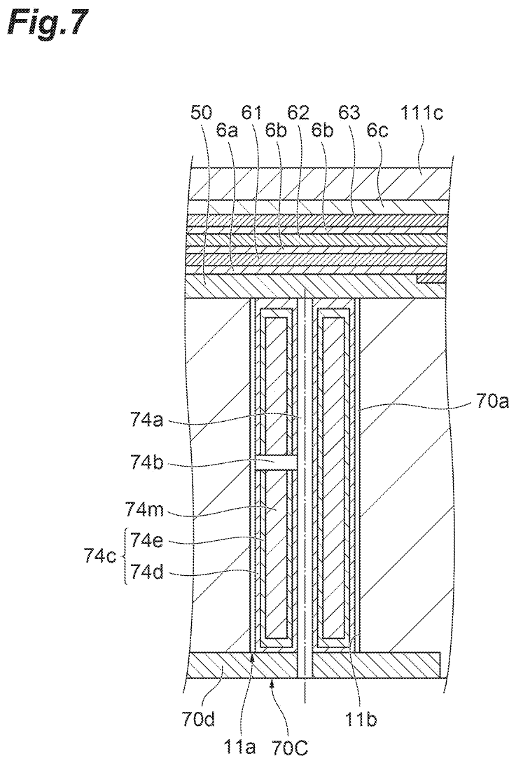

Hereinafter, reference is made to FIG. 7. FIG. 7 is an enlarged sectional view of a power feed line according to still another exemplary embodiment. The power feed line 70C illustrated in FIG. 7 can be adopted as each of the one or the plurality of power feed lines 70 described above. Hereinafter, the power feed line 70C will be described from the viewpoint of the differences between the power feed line 70C and the power feed line 70B.

The power feed line 70C includes a first metal film 74d and a second metal film 74e as the metal film 74c. The second metal film 74e is formed of metal different from metal that forms the first metal film 74d. For example, the first metal film 74d is formed of gold and the second metal film 74e is formed of palladium. The second metal film 74e is disposed between the first metal film 74d and the main body 74m. That is, the main body 74m is covered by two layers of metal film 74c including the first metal film 74d and the second metal film 74e.

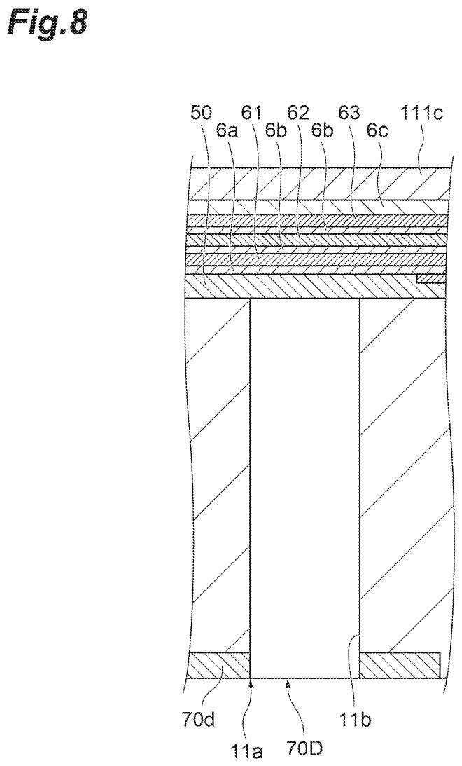

Hereinafter, reference is made to FIG. 8. FIG. 8 is an enlarged sectional view of a power feed line according to still another exemplary embodiment. The power feed line 70D illustrated in FIG. 8 can be adopted as each of the one or the plurality of power feed lines 70 described above. The power feed line 70D includes an inner wall 11b. The inner wall 11b defines at least one hole 11a. For example, the base 110 is formed of silicon carbide. The inner wall 11b is connected to the electrode 70d. The source radio frequency power or the electric bias is supplied from the electrode 70d to the corresponding electrode among the plurality of electrodes 50, through the inner wall 11b by the skin effect.

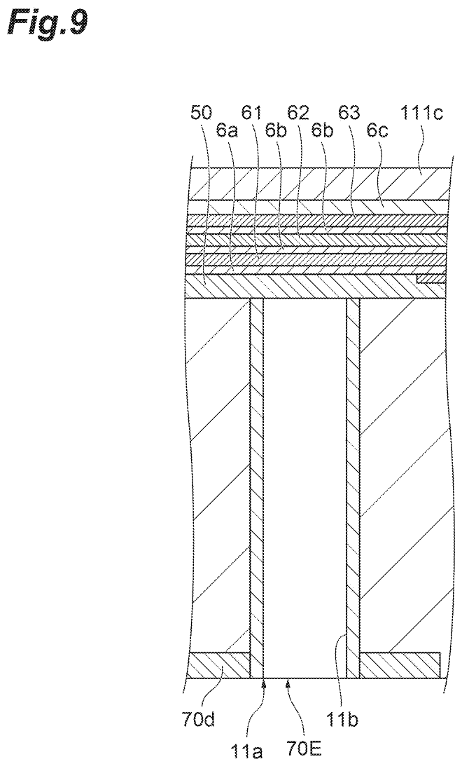

Hereinafter, reference is made to FIG. 9. FIG. 9 is an enlarged sectional view of a power feed line according to still another exemplary embodiment. The power feed line 70E illustrated in FIG. 9 can be adopted as each of the one or the plurality of power feed lines 70 described above. In the power feed line 70E, the inner wall 11b is formed of a conductor film. For example, the inner wall 11b is formed of a metal film. The conductor film that forms the inner wall 11b may contain palladium, nickel, or gold. The conductor film that forms the inner wall 11b is connected to the electrode 70d.

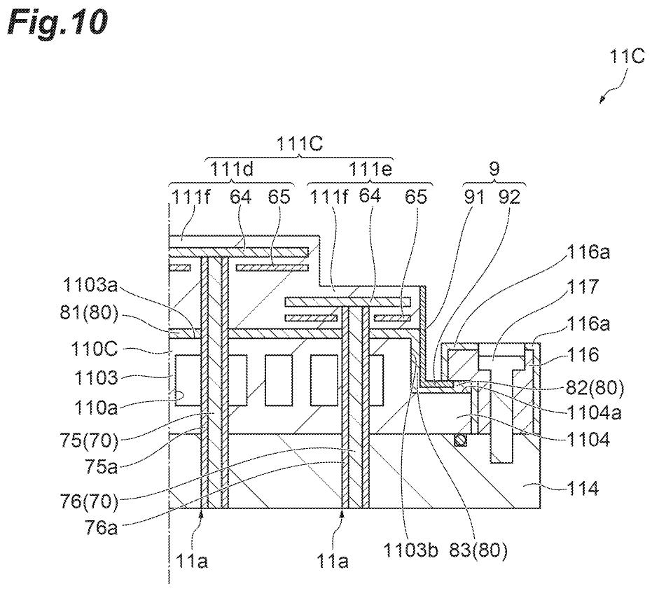

Hereinafter, reference is made to FIG. 10. FIG. 10 is a partially enlarged sectional view of a substrate support according to still another exemplary embodiment. The substrate support 11C illustrated in FIG. 10 can be adopted as a substrate support 11C of the plasma processing apparatus 1.

The substrate support 11C includes abase 110C, an electrostatic chuck 111C, a metal layer 80, and an insulating film 9. The base 110C is formed of ceramic. In an example, the base 110C is formed of silicon carbide, aluminum nitride, or aluminum oxide. The base 110C includes a central portion 1103 and a peripheral edge portion 1104. The central portion 1103 includes a first upper surface 1103a and a side surface 1103b. The side surface 1103b extends downward from a peripheral edge of the first upper surface 1103a. The peripheral edge portion 1104 extends along the circumferential direction to surround the central portion 1103. The peripheral edge portion 1104 includes a second upper surface 1104a. The second upper surface 1104a extends outward from a lower end of the side surface 1103b and extends at a position lower than the position of the first upper surface 1103a. The second upper surface 1104a is connected to the first upper surface 1103a by the side surface 1103b. The base 110C may provide a flow path 110a therein.

The electrostatic chuck 111C is provided on the first upper surface 1103a. In one embodiment, the electrostatic chuck 111C may include a central region 111d, an annular region 111e, and a dielectric layer 111f. The central region 111d is configured to support the substrate W placed thereon. The annular region 111e extends to surround the central region 111d and is configured to support the edge ring 112 placed thereon. The dielectric layer 111f provides a surface of the electrostatic chuck 111C. In an example, the dielectric layer 111f is formed of ceramic such as aluminum nitride, aluminum oxide, or yttrium oxide.

In one embodiment, each of the central region 111d and the annular region 111e of the electrostatic chuck 111C may include a first electrode layer 64 and a second electrode layer 65. In each of the central region 111d and the annular region 111e, the first electrode layer 64 and the second electrode layer 65 are covered by a dielectric layer 111f and are disposed in the dielectric layer 111f.

A DC power source may be electrically connected to the first electrode layer 64. When a voltage from the DC power source is applied to the first electrode layer 64 in the central region 111d, electrostatic attraction force is generated between the substrate W and the central region 111d. Further, when a voltage from the DC power source is applied to the first electrode layer 64 in the annular region 111e, electrostatic attraction force is generated between the edge ring 112 and the annular region 111e. As a result, the substrate W is held by the central region 111d, and the edge ring 112 is held by the annular region 111e. Further, in each of the central region 111d and the annular region 111e, either one or both of the source radio frequency power and the electric bias may be supplied from the electric power source 30 to the second electrode layer 65.

In an embodiment, the substrate support 11C provides at least one hole 11a. In the example illustrated in FIG. 10, the substrate support 11C provides a plurality of holes 11a. Each of the plurality of holes 11a extends from a lower surface of the base 110C. For example, each of the plurality of holes 11a extends toward the first electrode layer 64.

The substrate support 11C includes at least one power feed line 70. In one embodiment, the substrate support 11C includes a plurality of power feed lines 70. Each of the plurality of power feed lines 70 is connected to the first electrode layer 64.

As illustrated in FIG. 10, the plurality of power feed lines 70 may include the power feed lines 75 and 76. The power feed line 75 is connected to the first electrode layer 64 in the central region 111d. The power feed line 76 is connected to the first electrode layer 64 in the annular region 111e. Each of the power feed lines 75 and 76 may be formed of metal. In this case, the power feed lines 75 and 76 are respectively disposed in the sleeves 75a and 76a. Each of the sleeves 75a and 76a is formed of an insulating material. The insulating material that forms each of the sleeves 75a and 76a is, for example, ceramic.

The first electrode layer 64 may be electrically connected to a DC power source through at least one power feed line 70. The second electrode layer 65 may be electrically connected to the electric power source 30 that applies either one or both of the source radio frequency power and the electric bias through a power feed line provided in the substrate support 11C, as with at least one power feed line 70.

The metal layer 80 covers the surface of the base 110C. The metal layer 80 may be composed of a single layer or a plurality of layers. The metal layer 80 is formed of pure metal or an alloy. In an example, the metal layer 80 may be formed of aluminum, titanium, or tungsten. The metal layer 80 includes a first region 81, a second region 82, and a third region 83. The first region 81 is disposed between the first upper surface 1103a and the electrostatic chuck 111C. The first region 81 may bond the base 110C and the electrostatic chuck 111C to each other. The second region 82 is disposed on the second upper surface 1104a. The third region 83 extends along the side surface 1103b and electrically connects the first region 81 and the second region 82 to each other.

The insulating film 9 covers at least the third region 83. The insulating film 9 is formed of for example, aluminum oxide or yttrium oxide. In one embodiment, the insulating film 9 may include a first portion 91 and a second portion 92. The first portion 91 covers the side surface of the annular region 111e and the third region 83. In the example illustrated in FIG. 10, the first portion 91 extends to the upper surface of the annular region 111e. The second portion 92 covers at least a portion of the second region 82. The first portion 91 and the second portion 92 may be contiguous with each other.

In the substrate support 11C, the insulating film 9 covers at least the third region 83 of the metal layer 80. Therefore, the substrate support 11C suppresses the exposure of the metal layer 80 to the plasma processing space 10s. As a result, the loss of the metal layer 80 is suppressed. In the substrate support 11C, the base 110C and the electrostatic chuck 111C may be bonded to each other by the metal layer 80. Since the metal layer 80 has a relatively high thermal conductivity, the heat transfer efficiency from the electrostatic chuck 111C to the base 110C can be improved.

In one embodiment, the substrate support 11C may further include abase plate 114 and an insulating support ring. The base plate 114 is disposed under the base 110C. The base plate 114 supports the base 110C mounted thereon. The base plate 114 is formed of metal.

The base 110C may be fixed to the base plate 114. For example, the base 110C may be fixed to the base plate 114 by holding the peripheral edge portion 1104 between the clamp ring 116 and the base plate 114. The clamp ring 116 may be formed of metal, and the surface thereof may be covered with an insulating film 116a. The clamp ring 116 is fixed to the base plate 114 by a fixing screw 117. The clamp ring 116 and the fixing screw 117 may be covered with an insulating cover.

In the substrate support 11C, the insulating film 116a may be provided to expose the metallic lower surface of the clamp ring 116. The second portion 92 may be provided to expose a portion of the second region 82 facing the metallic lower surface of the clamp ring 116. The lower surface of the clamp ring 116 is in close contact with the base plate 114 and the second region 82. Therefore, the second region 82 and the base plate 114 are electrically connected to each other by the clamp ring 116. Therefore, the first region 81 is connected to a power feed line that includes the second region 82, the third region 83, the clamp ring 116, and the base plate 114.

In the substrate support 11C, a portion of the electric power source 30 may be electrically connected to the base plate 114. For example, the radio frequency power source 31 may be electrically connected to the base plate 114.

In an example illustrated in FIG. 10, the second region 82 is disposed on the second upper surface 1104a, in the substrate support 11C. Therefore, by connecting a power feed line to the second region 82 from the outer side of the base 110C, it is possible to establish an electrical path to the first region 81 without going through the interior of the base 110.

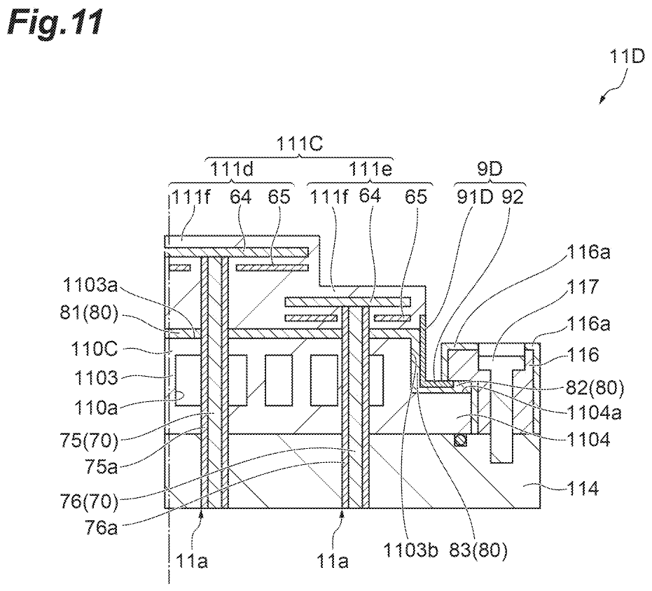

Hereinafter, reference is made to FIG. 11. FIG. 11 is a partially enlarged sectional view of a substrate support according to still another exemplary embodiment. The substrate support 11D illustrated in FIG. 11 can be adopted as a substrate support 11D in the plasma processing apparatus 1. Hereinafter, the substrate support 11D will be described from the viewpoint of the differences between the substrate support 11D and the substrate support 11C illustrated in FIG. 10.

The substrate support 11D includes an insulating film 9D instead of the insulating film 9. The insulating film 9D includes a first portion 91D in place of the first portion 91. The first portion 91D covers the third region 83, but does not extend to the upper surface of the annular region 111e. The first portion 91D covers only a portion of the side surface of the annular region 111e, that is, a portion adjacent to the third region 83. That is, the first portion 91D does not need to cover the entire side surface of the annular region 111e.

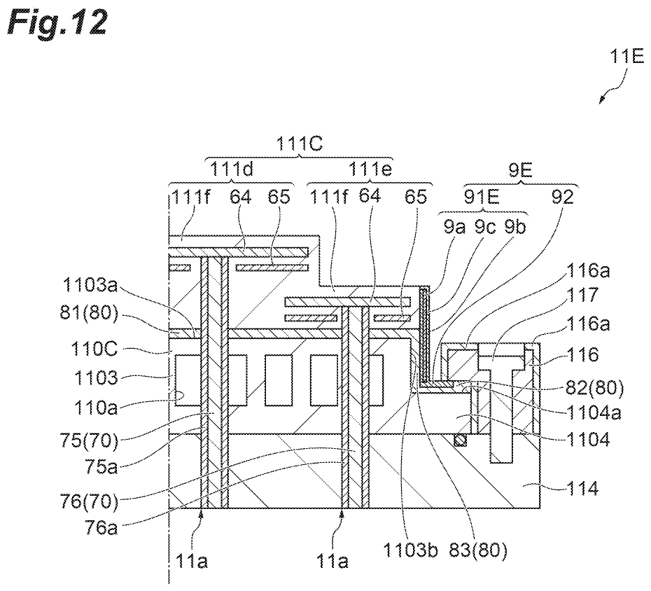

Hereinafter, reference is made to FIG. 12. FIG. 12 is a partially enlarged sectional view of a substrate support according to still another exemplary embodiment. The substrate support 11E illustrated in FIG. 12 can be adopted as a substrate support 11E in the plasma processing apparatus 1. Hereinafter, the substrate support 11E will be described from the viewpoint of the differences between the substrate support 11E and the substrate support 11C illustrated in FIG. 10.

The substrate support 11E includes an insulating film 9E instead of the insulating film 9. The insulating film 9E includes a first insulating film 9a, a second insulating film 9b, and a third insulating film 9c. The first insulating film 9a is disposed at the innermost side among the first insulating film 9a, the second insulating film 9b, and the third insulating film 9c. The first insulating film 9a may be in contact with the third region 83 and the side surface of the annular region 111e. The second insulating film 9b is disposed on the outermost side so that the third insulating film 9c is interposed between the first insulating film 9a and the second insulating film 9b. The third insulating film 9c is disposed between the first insulating film 9a and the second insulating film 9b. In an example, the first insulating film 9a is formed of polyimide. The second insulating film 9b may be formed of ceramic. In an example, the second insulating film 9b is formed of aluminum oxide or yttrium oxide. The insulation resistance of the first insulating film 9a may be larger than the insulation resistance of the second insulating film 9b.

In the example illustrated in FIG. 12, the insulating film 9E includes a first portion 91E instead of the first portion 91. The first portion 91E includes a first insulating film 9a, a second insulating film 9b, and a third insulating film 9c. The insulating film 9E, as with the insulating film 9, may further include the second portion 92. The second portion 92 may not include the first insulating film 9a, the second insulating film 9b, and the third insulating film 9c, and may be formed of a single film. Alternatively, the second portion 92 may include the first insulating film 9a, the second insulating film 9b, and the third insulating film 9c, and may be formed of a plurality of films. In the first portion 91E, the first insulating film 9a may be disposed on the third region 83, the third insulating film 9c may be disposed on the first insulating film 9a, and the second insulating film 9b may be disposed on the third insulating film 9c.

The second portion 92 may be formed of the same material as the material of the second insulating film 9b. In an example, the second portion 92 and the second insulating film 9b are formed of aluminum oxide or yttrium oxide. In this case, the second portion 92 may be contiguous with the lower end of the second insulating film 9b of the first portion 91E. Alternatively, the second portion 92 may be formed of the same material as the material of the first insulating film 9a. In an example, the second portion 92 and the first insulating film 9a are formed of polyimide. In this case, the second portion 92 may be contiguous with the lower end of the first insulating film 9a of the first portion 91E.

In one embodiment, the third insulating film 9c includes a base material and a plurality of granular materials dispersed in the base material. The plurality of granular materials include exposed portions that are exposed from the base material, and these exposed portions are in contact with the first insulating film 9a and the second insulating film 9b. In an example, the base material contains a resin or a silane-based agent. The silane-based agent is an example of an inorganic material containing silicon and oxygen. Each of the plurality of granular materials is formed of ceramic. The third insulating film 9c can bond the first insulating film 9a and the second insulating film 9b. According to such insulating film 9E, a high adhesion of the insulating film 9E to the third region 83 and the side surface of the annular region 111e is secured.

Although the various exemplary embodiments have been described above, various additions, omissions, substitutions, and changes may be made without being limited to the exemplary embodiments described above. In addition, elements from different embodiments can be combined to form other embodiments.

For example, in another embodiment, the plasma processing apparatus may be a capacitively coupled plasma processing apparatus, an inductively coupled plasma processing apparatus, an Electron-Cyclotron-Resonance Plasma (ECR) processing apparatus, a Helicon Wave Plasma (HWP) processing apparatus, or a Surface Wave Plasma (SWP) processing apparatus, separate from the plasma processing apparatus 1.

Here, the various exemplary embodiments included in the present disclosure are described in [E1] to [E20] below.

[E1]

A substrate support used in a plasma processing apparatus, comprising:
a base formed of ceramic;
an electrostatic chuck disposed on the base; and
a plurality of electrodes,
wherein the electrostatic chuck includes
   a central region configured to support a substrate placed thereon,
   an annular region that extends to surround the central region and is configured to support an edge ring placed thereon, and
   a coating layer configuring a surface of the electrostatic chuck, and
the plurality of electrodes include
   a first metal layer disposed between the central region and the base, and
   a second metal layer disposed between the annular region and the base.

[E2]

The substrate support according to E1, wherein the electrostatic chuck includes
a first resin layer disposed on the base,
an electrode layer disposed on the first resin layer, and
a second resin layer disposed between the electrode layer and the coating layer.

[E3]

The substrate support according to E1 or E2,
wherein the base includes a first base and a second base disposed on the first base,
the first metal layer is disposed on the second base,
the plurality of electrodes include a third metal layer disposed between the first base and the second base, and
the third metal layer bonds the first base and the second base to each other.

[E4]

The substrate support according to E3, wherein the second metal layer is provided on the second base.

[E5]

The substrate support according to E4,
wherein the first base includes a peripheral edge portion that protrudes outward with respect to an outer edge of the second base,
the plurality of electrodes include a fourth metal layer disposed on the peripheral edge portion, and
the third metal layer and the fourth metal layer are electrically connected to each other.

[E6]

The substrate support according to E3,
wherein the first metal layer is disposed on the second base, and
the second metal layer is disposed on the first base.

[E7]

The substrate support according to any one of E1 to E6,
wherein the substrate support provides at least one hole extending from a lower surface of the base, and
the substrate support further comprises at least one power feed line extending through the at least one hole and connected to at least one of the plurality of electrodes.

[E8]

The substrate support according to E7, wherein the at least one power feed line includes a power feed conductor extending in the at least one hole.

[E9]

The substrate support according to E8, wherein the power feed conductor is formed of metal.

[E10]

The substrate support according to E9, wherein the metal is titanium, molybdenum, or tungsten.

[E11]

The substrate support according to E8, wherein the power feed conductor is formed of silicon carbide.

[E12]

The substrate support according to E8, wherein the power feed conductor is formed of silicon.

[E13]

The substrate support according to any one of E8 to E12, wherein the at least one power feed line includes
a main body, and
at least one metal film covering a surface of the main body.

[E14]

The substrate support according to E13, wherein the at least one metal film includes
a first metal film, and
a second metal film formed of metal different from metal forming the first metal film, and disposed between the first metal film and the main body.

[E15]

The substrate support according to E13 or E14, wherein the at least one metal film includes palladium, nickel, or gold.

[E16]

The substrate support according to any one of E8 to E15, wherein the power feed line includes an inner wall that defines the at least one hole.

[E17]

The substrate support according to E16, wherein the inner wall is formed of a conductor film.

[E18]

A plasma processing apparatus comprising:
a plasma processing chamber; and
the substrate support according to any one of E1 to E17, disposed in the plasma processing chamber.

[E19]

A substrate support used in a plasma processing apparatus, comprising:
a base formed of ceramic, including
   a central portion including a first upper surface and a side surface extending downward from a peripheral edge of the first upper surface, and
   a peripheral edge portion including a second upper surface and extending along a circumferential direction to surround the central portion, the second upper surface extending outward from a lower end of the side surface and extending at a lower position than a position of the first upper surface;
an electrostatic chuck disposed on the first upper surface;
a metal layer including a first region disposed between the first upper surface and the electrostatic chuck, a second region disposed on the second upper surface, and a third region extending along the side surface to electrically connect the first region and the second region to each other; and
an insulating film covering at least the third region.

[E20]

A plasma processing apparatus, comprising:
a plasma processing chamber; and
the substrate support according to E19, disposed in the plasma processing chamber.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the aspects following claims.

What is claimed is:

1. A substrate support used in a plasma processing apparatus, comprising:
a base formed of ceramic;
an electrostatic chuck disposed on the base; and
a plurality of electrodes,
wherein the electrostatic chuck includes
a central region configured to support a substrate placed thereon,
an annular region that extends to surround the central region and is configured to support an edge ring placed thereon, and
a coating layer configuring a surface of the electrostatic chuck, and
the plurality of electrodes include
a first metal layer disposed between the central region and the base, and
a second metal layer disposed between the annular region and the base.

2. The substrate support according to claim 1, wherein the electrostatic chuck includes
a first resin layer disposed on the base,
an electrode layer disposed on the first resin layer, and
a second resin layer disposed between the electrode layer and the coating layer.

3. The substrate support according to claim 1,
wherein the base includes a first base and a second base disposed on the first base,
the first metal layer is disposed on the second base,
the plurality of electrodes include a third metal layer disposed between the first base and the second base, and
the third metal layer bonds the first base and the second base to each other.

4. The substrate support according to claim 3, wherein the second metal layer is disposed on the second base.

5. The substrate support according to claim 4,
wherein the first base includes a peripheral edge portion that protrudes outward with respect to an outer edge of the second base,
the plurality of electrodes include a fourth metal layer disposed on the peripheral edge portion, and
the third metal layer and the fourth metal layer are electrically connected to each other.

6. The substrate support according to claim 3,
wherein the first metal layer is disposed on the second base, and
the second metal layer is disposed on the first base.

7. The substrate support according to claim 1,
wherein the substrate support provides at least one hole extending from a lower surface of the base, and
the substrate support further comprises at least one power feed line extending through the at least one hole and connected to at least one of the plurality of electrodes.

8. The substrate support according to claim 7, wherein the at least one power feed line includes a power feed conductor extending in the at least one hole.

9. The substrate support according to claim 8, wherein the power feed conductor is formed of metal.

10. The substrate support according to claim 9, wherein the metal is titanium, molybdenum, or tungsten.

11. The substrate support according to claim 8, wherein the power feed conductor is formed of silicon carbide.

12. The substrate support according to claim 8, wherein the power feed conductor is formed of silicon.

13. The substrate support according to claim 8, wherein the at least one power feed line includes
a main body, and
at least one metal film covering a surface of the main body.

14. The substrate support according to claim 13, wherein the at least one metal film includes
a first metal film, and
a second metal film formed of metal different from metal forming the first metal film, and disposed between the first metal film and the main body.

15. The substrate support according to claim 13, wherein the at least one metal film includes palladium, nickel, or gold.

16. The substrate support according to claim 8, wherein the power feed line includes an inner wall that defines the at least one hole.

17. The substrate support according to claim 16, wherein the inner wall is formed of a conductor film.

18. A plasma processing apparatus comprising:
a plasma processing chamber; and
the substrate support according to claim 1, disposed in the plasma processing chamber.

19. A substrate support used in a plasma processing apparatus, comprising:
a base formed of ceramic, including
a central portion including a first upper surface and a side surface extending downward from a peripheral edge of the first upper surface, and
a peripheral edge portion including a second upper surface and extending along a circumferential direction to surround the central portion, the second upper surface extending outward from a lower end of the side surface and extending at a lower position than a position of the first upper surface;
an electrostatic chuck disposed on the first upper surface;
a metal layer including a first region disposed between the first upper surface and the electrostatic chuck, a second region disposed on the second upper surface, and a third region extending along the side surface to electrically connect the first region and the second region to each other; and
an insulating film covering at least the third region.

20. A plasma processing apparatus, comprising:
a plasma processing chamber; and
the substrate support according to claim 19, disposed in the plasma processing chamber.
